(19) United States
(12) Patent Application Publication
(10) Pub. No.: US 2024/0153928 A1
(43) Pub. Date: May 9, 2024

(54) OPTOELECTRONIC ASSEMBLY, DISPLAY ARRANGEMENT AND METHOD

(71) Applicant: ams-OSRAM International GmbH, Regensburg (DE)

(72) Inventors: Siegfried Herrmann, Neukirchen (DE); Korbinian Perzlmaier, Regensburg (DE); Alexander Pfeuffer, Regensburg (DE)

(21) Appl. No.: 18/550,213

(22) PCT Filed: Mar. 15, 2022
(86) PCT No.: PCT/EP2022/056610

§ 371 Date: Sep. 12, 2023

(30) Foreign Application Priority Data
Mar. 16, 2021 (DE) 102021106332.9

(51) Int. Cl. H01L 25/075; H01L 33/48; H01L 33/50; H01L 33/60; H01L 33/62

(52) U.S. Cl. CPC H01L 25/0753; H01L 33/486; H01L 33/507; H01L 33/60; H01L 33/62

(57) ABSTRACT

In an embodiment an optoelectronic assembly includes a carrier having at least one contact region, at least one optoelectronic device arranged on the at least one contact region, a beam guiding element having a transparent material, arranged on the carrier, completely encasing the optoelectronic device and at least partially covering surface areas of the optoelectronic device, wherein the beam guiding element sheaths at least three optoelectronic devices and covers the surface areas of the optoelectronic devices, and wherein the optoelectronic devices are configured to generate light of different colors and a transparent conductive layer arranged at the beam guiding element at least in some regions on its surface, wherein the beam guiding element has a recess through which the at least one contact region is exposed on a side of the optoelectronic device facing away from the carrier, and wherein the recess is at least partially filled with a conductive material which is connected to the transparent conductive layer.

### CROSS-REFERENCE TO RELATED APPLICATIONS

This patent application is a national phase filing under section 371 of PCT/EP2022/056610, filed Mar. 15, 2022, which claims the priority of German patent application 102021106332.9, filed Mar. 16, 2021, each of which is incorporated herein by reference in its entirety.

### TECHNICAL FIELD

The present invention relates to an optoelectronic assembly and a method of manufacturing the same. The invention further relates to a display comprising such an assembly.

### BACKGROUND

Due to the increasing miniaturization of optoelectronic devices, e.g. in pixelated arrays or also displays with very small LEDs, for example in μLEDs, it may happen that the coupling out of radiation from the semiconductor body can no longer be influenced sufficiently well. This is due to the fact that, on the one hand, optoelectronic devices with very small lateral dimensions in the range of less than 70 μm down to a few μm (so-called μLEDs) have different properties and, on the other hand, measures to influence the coupling-out and the radiation characteristics can no longer be implemented or can only be implemented with increased effort.

Thus, despite its thickness of 5 μm or less (typically 2 μm or less), a μLED increasingly behaves as a volume emitter due to its small lateral dimensions of <100 μm to <10 μm without side mirroring and exhibits a radiation pattern that differs from a so-called Lambertian radiator. This characteristic can lead to altered visual impressions on the part of a user in some applications. For example, in the case of direct-emitting displays (e.g. video wall, μLED display), the brightness of the display changes depending on the viewing angle due to the non-Lambertian radiation behaviour.

In the case of direct backlighting of TFT displays, e.g. with mini-LEDs, on the other hand, reduced radiation in the forward direction is desirable in order to be able to distribute the light of the backlighting better. However, lateral radiation of the (especially blue) InGaN LEDs can cause short-wave light to hit components with InGaAlP as a material system, which can lead to accelerated aging of this material system.

### SUMMARY

Embodiments provide an optoelectronic assembly, a display, and a method of manufacturing the same.

Embodiments further provide modifying the emission properties of an optoelectronic device, typically a volume emitter with significant light extraction through the side surfaces, in that after positioning on a substrate, the optoelectronic devices are first coated over their surface with a transparent material. This material is then brought into the target shape by lithography and etching and/or temperature steps. Subsequently, additional optical systems can be aligned and connected to the jacketed optoelectronic devices to realize integrated optical systems with the desired properties.

In one aspect, an optoelectronic assembly includes a substrate having at least one contact region, and at least one optoelectronic device disposed on the contact region and configured as a volume emitter for generating electromagnetic radiation. The optoelectronic device can be designed as a μLED, whereby in such a case an edge length is less than 70 μm and in particular is less than 20 μm and in particular is in the range of 2 μm to 15 μm. Furthermore, a beam-guiding element with a transparent material is provided, which is arranged on the carrier and completely encases the at least one optoelectronic device. The surface areas of the optoelectronic device emitting in operation are at least partially covered by the transparent material.

The beam guiding element thus causes a further redistribution of the emitted light, so that slight fluctuations in the position of the optoelectronic device resulting from the transfer can be compensated and the effective radiation is less affected thereby. This effect can also be complemented or enhanced by the measures described further below.

In one aspect, an optical assembly is additionally provided, which is arranged above the beam guiding element. The optical assembly may optionally include a support carrier for holding one or more optical elements. Thus, it is possible to implement complete optical systems with different optical elements such as lenses, converters, filters and others as an integrated assembly and thus achieve the desired characteristics depending on the application.

Another aspect deals with the shape of the steel-forming element. In principle, this may have a different basic shape as the optoelectronic element. However, in one aspect, a base shape of the beam shaping element corresponds to a shape of the base of the optoelectronic device and, in this shape, overhangs the optoelectronic device. For example, the base shape may be square or rectangular. This leads to an improvement in light guiding properties due to the symmetry between the optoelectronic device and the beam-shaped element.

In this regard, in some aspects, it may be provided that the beam guiding element encases at least 2 optoelectronic devices configured as volume emitters as well as covers the surface regions of the optoelectronic devices emitting in an operation. Likewise, the beam-guiding element can encase at least three optoelectronic devices designed as volume emitters as well as cover the surface regions of the optoelectronic devices emitting in one operation. In such a case, the optoelectronic devices can be designed to generate light of different colors, in particular of the colors red, green and blue, in one operation. In these embodiments, it is deliberately accepted that the beam-guiding element covers and encases several components designed as volume emitters. As a result, the light from these is mixed, and thus mixed colors are generated directly in the optical system and distributed more evenly over the area used by the optoelectronic devices. A possible impression of distributed colors is counteracted in this manner. In some aspects, pixels of sub-pixels of different colors (by the optoelectronic devices of different colors) can be generated in this manner by the beam carrying element.

In some aspects, the beam guiding element comprises a reflective layer, and in particular a reflective metallic layer, at least in regions adjacent to the side surfaces of the optoelectronic device. In this way, light is prevented from radiating downwardly to the side, but is instead directed upwardly, i.e., away from the device. In a further aspect, the beam guiding element comprises a reflective layer and in particular a metallic reflective layer on a side opposite to the support. In this embodiment, however, regions adjacent to the side surfaces of the optoelectronic device remain at least partially translucent. As a result, light can be selectively deflected away to the side so that applications for backlighting can be realized.

Moreover, in further aspects, it may be provided that the beam guiding element, comprises particles, e.g. converters or reflection particles. In this way, additional functionalities can be accommodated in or combined with the material of the beam guiding element. For example, white light or light of a different color can be easily generated using suitable converter materials. Likewise, RGB pixels can be generated in this way.

Another aspect deals with the electrical contacting of the device surrounded by the transparent material. In some aspects, a transparent conductive layer may be deposited on the beam-guiding element at least in some regions. This allows contact areas on the surface of the device to be electrically connected. To this end, in some aspects, the beam carrying element comprises a recess through which a contact region is exposed on a side of the optoelectronic device facing away from the substrate. This is convenient when the optoelectronic device is configured as a vertical LED and thus has the contacts on opposing surfaces.

In some aspects, the recess may be at least partially filled with a conductive material that is bonded to a conductive transparent material on the surface of the beam-guiding element. This provides contacting without significantly affecting brightness due to absorption. In one aspect, the recess forms a breakthrough, particularly a cylindrical breakthrough.

In addition to the measures presented herein, the beam-guiding element may have other geometric structures created during the manufacture thereof. For example, in some aspects, the beam-carrying element has a curved top surface, in particular forming a lens. This may have been created by an additional partial melting step. Similarly, depending on the material, surface tension, wetting properties, and other physical effects can also be used to create such lenses or other optical elements. In some aspects, the beam-carrying element can be part of a waveguide or at least have such functionality by virtue of its embodiment.

Various materials are conceivable for the beam-carrying element, such as SiO₂, spin-on glasses, silicone-containing materials, or acrylic or acrylic-containing materials may be used. Low melting glasses based on tellurite glass, bismuth glass, vanadate glass are also suitable. In some aspects, the beam guiding element may include scattering particles, particularly based on TiO₂, converter materials for converting light of a first wavelength to light of a second wavelength, or quantum dot converters.

To provide further optical properties, in some aspects the optoelectronic assembly may comprise an optical assembly. This is arranged above the beam carrying element. The optical assembly may be separately embodied with its own carrier in which one or more optical elements are disposed or supported by the carrier. The arrangement and the position of the optical elements is selected in such a way that after an alignment these are arranged over the beam-carrying elements. In this regard, the alignment may be in a 1:1 mapping. However, in some aspects, optical elements may be provided that span multiple beam carrying elements and thus multiple optoelectronic devices.

Various optical elements may be used for further conditioning and processing. For example, in one aspect, the optical assembly may include one or more lenses. Similarly, λ/2 or λ/4 layers may be provided. In one aspect, the optical element may also include layers comprising converter material for converting light of a first wavelength to light of a second wavelength or quantum dot systems. Finally, the optical element may have photonic structures. Several of these optical elements may be combined.

In another aspect, the arrangement and alignment of the carriers with the optoelectronic device(s) and the beam-guiding elements and the optical assembly is addressed. In some aspects, at least three spacers are provided for this purpose, which are arranged on the carrier or on the optical assembly and are configured to fix the optical assembly at a defined distance from the carrier and, in particular, from the beam-guiding element. More than three spacers can also be formed. Similarly, it is possible to visually or even haptically control the spacers via precise position markers to achieve precise positioning. In some aspects, structures are disposed on the optoelectronic device carrier or also on the optical assembly carrier. They are configured to interact with the spacers during alignment and positioning to effect accurate positioning. These structures may be, for example, slight indentations.

In some aspects, at least some of the spacers may be formed by beam-guiding elements, wherein the beam-guiding elements in particular have a planar top surface. This allows for ease of fabrication and good bonding without additional refractive index jumps due to voids, particularly when the beam-guiding elements have the same height.

In some aspects, the optical assembly is arranged over at least three beam-guiding elements, each of which surrounds at least one optoelectronic device, and which in operation generate light of different wavelengths, in particular in the colors red, green and blue. Thus, a plurality of beam-guiding elements can be combined into groups over which an optical assembly is arranged. In this way, pixels having three subpixels can be combined with additional optical elements. In another aspect, a beam-guiding element that fully encapsulates the at least one optoelectronic device is spaced apart from an adjacent beam-guiding element that fully encapsulates at least one additional optoelectronic device. The spacing reduces optical crosstalk and interference between different beam-guiding elements.

The proposed assembly can be used to form a display arrangement. Thus, in some aspects, one or more optoelectronic assemblies are arranged on a carrier according to the proposed principle. Further, a drive circuit for driving the optoelectronic devices of the at least one assembly is provided. This can be part of the carrier, but can also be present separately. Thus, the carrier may further comprise a plurality of feed lines which are connected to the optoelectronic devices of each optoelectronic assembly.

Another aspect deals with a method of manufacturing an optoelectronic assembly according to the proposed principle. Thus, in one method, a carrier having at least one contact region is provided. An optoelectronic device designed as a volume emitter for generating electromagnetic radiation is formed, in particular a μLED, and this is arranged on the at least one contact region. The optoelectronic device can be formed separately and arranged on the carrier by means of a transfer process. It is also possible to create optoelectronic devices directly on the carrier by means of manufacturing steps. Thus, the carrier with the optoelectronic devices can be provided as a pixelated array.

In the next step, a transparent material is applied to the carrier and the at least one optoelectronic device. This is done in such a way that the latter is completely surrounded by the transparent material. The applied transparent material is structured and a beam guiding element is formed therefrom. The beam-guiding element completely encases the at least one optoelectronic device and at least partially covers the surface regions of the optoelectronic device that emit during operation. With further steps, such as a renewed heating or other measures, the shape of the beam-conducting element or also its surface can be suitably shaped. For example, the beam-carrying element may have a planar surface but also a lenticular structure. The beam carrying element may be further shaped by various measures such that the surface exhibits a hyperbolic, circular, parabolic, or even elliptical shape in a cross-section.

In one aspect, when the transparent material is patterned, a photoresist is applied to the transparent material and the photoresist is then patterned and exposed to light. In some aspects, this is done such that a shape of the patterned photoresist corresponds to a shape of the footprint of the optoelectronic device.

For further forming the beam guiding element, the transparent material between regions of two optoelectronic devices is at least partially removed such that the transparent material surrounding the optoelectronic device is spaced apart from a material surrounding an adjacent optoelectronic device. However, it may also be provided that the patterned material surrounds a plurality of optoelectronic devices so that they are grouped therewith. In this manner, in some aspects, optoelectronic devices for generating light of different colors may be grouped together to form a pixel.

Some aspects deal with light guiding and orientation of light extraction. In some aspects, a reflective layer, particularly a reflective metallic layer, is applied during a formation of a beam guiding element. This is done at least in regions adjacent to the side surfaces of the optoelectronic device. As a result, light that is emitted in the direction of the side surfaces is reflected and reflected upwards, i.e. away from the optoelectronic device. Alternatively, a reflective layer, in particular a metallic reflective layer, can be applied to a side of the beam-guiding element opposite the substrate. In this case, at least areas adjacent to the side surfaces of the optoelectronic device remain at least partially translucent. Thus, a light guidance towards the side is achieved, so that such assemblies can be used for a background illumination.

In order to still ensure light transmission in this context, it may be provided to apply a transparent conductive layer to at least some areas of the beam guiding element. In this way, electrical contacting of the optoelectronic device can be provided via the beam-carrying element.

To this end, in some aspects, it may be provided that a recess is formed in the beam carrying element. This recess exposes a contact region on a side of the optoelectronic device facing away from the carrier. This is convenient if the optoelectronic device is formed by a vertical light-emitting diode in which the contacts are on opposite surfaces. Subsequently, the recess can be at least partially filled, or lined, with a conductive material. This conductive material is electrically conductively connected to a conductive material on a surface of the beam-guiding element. As a result, full electrical contact is achieved. In some aspects, the recess is formed with a hole or breakthrough and in particular a cylindrical breakthrough. However, other shapes are also possible. Similarly, the recess need not be rotationally symmetrical with respect to the rest of the beam-carrying element, but may be formed as a mere punch-out of the material of the beam-carrying element.

In various aspects, the beam carrying element can be further formed. In some aspects, a shape of the beam guiding element can be further formed by localized heating or melting. For example, a curved top surface, and in particular a top surface forming a lens, is implemented by downstream partial melting.

Another aspect deals with the grouping and embodiment of the optoelectronic devices. In some aspects of the proposed method, at least 2 optoelectronic devices configured as volume emitters are formed or arranged on the substrate. A different number may also be employed herein. Thus, in some aspects, a plurality of optoelectronic devices configured as volume emitters are formed and are grouped together. In some aspects, each group comprises optoelectronic devices that, in one aspect of operation, generate light of different colors, particularly the colors red, green, and blue.

In another aspect, the transparent material is then patterned and the beam guiding element is formed such that a plurality of optoelectronic devices are each surrounded by a common beam guiding element. In this way, groups are formed. For example, three optoelectronic devices for generating different colors can thus be combined into one group and one pixel. It is possible in this context that the beam-carrying element contains reflection particles to achieve uniform radiation.

In further aspects, an optical assembly may be provided to create an integrated optical system. The optical assembly is disposed and aligned over the beam carrying element. The optical assembly is then fixed to the support so that the optical assembly is at a defined distance from the support and, in particular, from the beam carrying element. The optical assembly may comprise one or more or combinations of different optical elements. Thus, one or more lenses, waveguides or λ/2 or λ/4 layers may be provided. Converters for converting light of a first wavelength to light of a second wavelength, or photonic structures, are likewise conceivable as optical elements.

Another aspect deals with the arrangement and positioning of the optical component on the carrier. To this end, in some aspects, it may be provided to form or provide the carrier with at least three spacers. The spacers are configured to fix the optical assembly at a defined distance from the carrier and, in particular, from the beam guiding element. Alternatively, the optical assembly can also be designed or provided with at least three spacers. Of course, more than three spacers are also conceivable and, moreover, these can also be implemented on both elements, i.e. the carrier and the optical assembly. The spacers, serve to fix the optical assembly at a defined distance from the carrier and in particular from the beam guiding element. In some aspects, markers can be used for accurate or improved positioning. Similarly, it is possible to provide positioning or gripping elements on the respective other element such that the spacers engage therein and are held by them. In some aspects, a recess is created in the carrier or optical assembly for this purpose. These can further assist in accurate positioning.

In one aspect, at least some spacers are formed by the beam carrying elements. In other words, the optical assembly is placed on the beam carrying elements so that it is supported by the beam carrying elements. For this purpose, the beam-carrying elements may in particular have a planar upper surface. In some aspects, the optical elements of the optical assembly are disposed over exactly one beam carrying element. However, it may also be provided that an optical element is arranged over at least three beam-carrying elements, each of which surrounds at least one optoelectronic device, and which optionally generate light of different wavelengths, in particular in the colors red, green and blue, in one operation.

### BRIEF DESCRIPTION OF THE DRAWINGS

Further aspects and embodiments according to the proposed principle will be revealed with reference to the various embodiments and examples described in detail in connection with the accompanying drawings.

FIG. 1 shows a first embodiment of an optoelectronic assembly having some aspects of the proposed principle;

FIG. 2 shows a second embodiment of an optoelectronic assembly with some aspects of the proposed principle;

FIG. 3 represents a perspective view of a further embodiment of an optoelectronic assembly, the elements of which are realized differently to illustrate some aspects of the proposed principle;

FIG. 4 represents a perspective view of an embodiment of an optoelectronic assembly for illustrating some aspects;

FIG. 5 is a perspective view of another embodiment of an optoelectronic assembly for illustrating some aspects;

FIG. 6 is a perspective view showing an optical assembly disposed over a carrier;

FIG. 7 is a perspective sectional view of a further embodiment of an optoelectronic assembly to illustrate some aspects;

FIG. 8 shows a cross-sectional view of a further embodiment to illustrate some aspects;

FIG. 9 shows a display arrangement with an optoelectronic assembly according to the proposed principle

FIG. 10 shows an embodiment of a process in several steps for manufacturing an optical assembly;

FIG. 11 shows 2 process steps for producing an optoelectronic device according to some aspects of the proposed principle;

FIG. 12 shows a further process step for producing an optoelectronic device with some aspects of the proposed principle;

FIG. 13 shows a further process step for generating an optoelectronic device with some aspects of the proposed principle; and

FIG. 14 shows a step of positioning an optical assembly illustrating some aspects of the proposed principle.

### DETAILED DESCRIPTION OF ILLUSTRATIVE EMBODIMENTS

The following embodiments and examples illustrate various aspects and their combinations according to the proposed principle. The embodiments and examples are not always to scale. Likewise, various elements may be shown enlarged or reduced in size to highlight individual aspects. It will be understood that the individual aspects and features of the embodiments and examples shown in the figures may be readily combined with each other without affecting the principle of the invention. Some aspects have a regular structure or shape. It should be noted that minor deviations from the ideal shape may occur in practice, but without contradicting the inventive idea.

In addition, the individual figures, features and aspects are not necessarily shown in the correct size, nor are the proportions between the individual elements necessarily fundamentally correct. Some aspects and features are emphasized by showing them enlarged. However, terms such as “above”, “above”, “below”, “below”, “larger”, “smaller” and the like are correctly represented in relation to the elements in the figures. Thus, it is possible to derive such relationships between the elements based on the figures. In the embodiments, the optoelectronic devices are μLEDs. However, the proposed principle is not limited to this, but different optoelectronic device, with different size and also functionality can be used in the invention. Thus, an optical system according to the proposed principle can also be realized with sensors as optoelectronic devices.

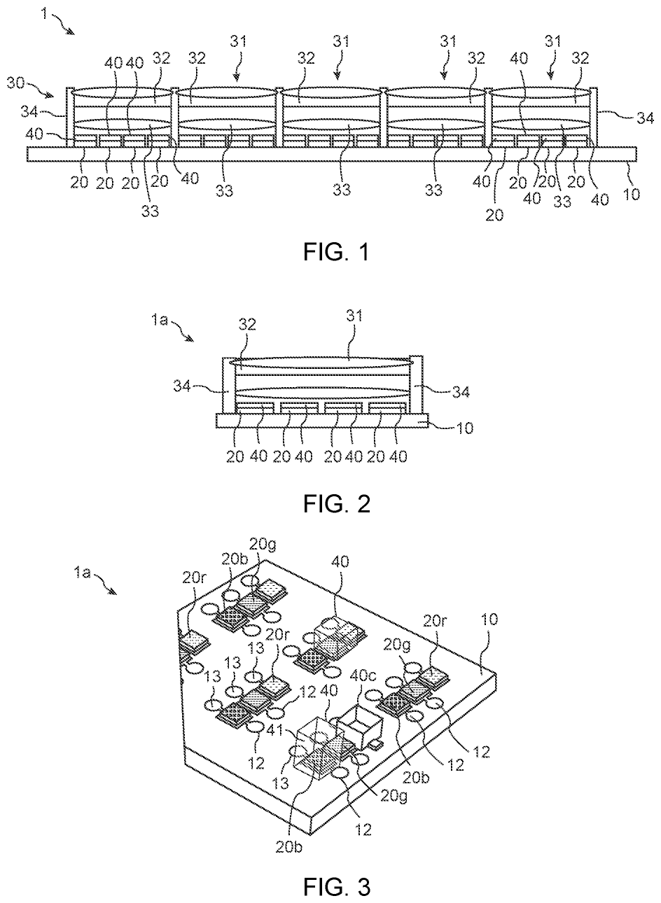

FIG. 1 shows a first embodiment example with a plurality of optoelectronic assemblies according to the proposed principle. In the present embodiment example, the optoelectronic assemblies 1 are arranged side by side on a substrate carrier 10. In the embodiment example, each electronic assembly 1 comprises 4 optoelectronic devices or μLEDs 20, each of which is combined into a group. Each of the optoelectronic devices 20 is in turn completely surrounded by a beam-guiding element 40, which, in simplified form, is arranged on the respective optoelectronic device 20. An optical assembly 30 is again arranged above each of 4 optoelectronic devices 20 combined to form a group.

The optical assembly 30 comprises 2 spacers 34 and a plurality of optical elements 31, 32 and 33 arranged therebetween. The latter are in turn stacked on top of each other to form an optical lens system. Specifically, a first optical lens 33 is arranged above the 4 optoelectronic devices with their associated beam guiding elements 40. A first structure 32 is provided above the lens and a second lens 31 is provided above it. In this embodiment, an integrated optical system is thus formed from the optoelectronic assemblies on the carrier 10 and the optical assembly 30. Several such optical systems can be combined to form an array or display.

Precise alignment of the individual components, in particular the optical assembly 30 directly above the optoelectronic devices 20 and their beam guiding elements 40, is ensured. In this way, lenses and other optical elements with macroscopic dimensions can be assembled into optical systems, with the optoelectronic devices and beam-guiding elements themselves having edge lengths of only a few micrometers. In this case, the positioning of the optical assembly above the optoelectronic assembly allows a high accuracy between the optical lenses 33 and the beam guiding elements 40 in the order of 1/10 μm.

FIG. 2 shows an embodiment of a single optoelectronic assembly provided with an optical system. The optoelectronic assembly comprises a carrier 10 on which a plurality of optoelectronic devices 20 in the form of μLEDs are arranged as in the previous example. Each μLED is electrically connected to one or more contacts on the surface of the carrier 10 for driving.

A transparent beam guiding element 40 surrounds each μLED 20 from all sides and also covers it. In one operation, the μLED emits light as a volume emitter not only over the main surface but also along the side surfaces and thus in any direction. The beam guiding element 40 redirects this light in a particular direction, and in this case the redirection is upward. An optical assembly 30 with a plurality of lenses 31 and 33 or further optical elements 32 is again arranged above the beam-guiding elements 40. Together with the beam-guiding elements, they thus form an optical system. Spacers 34 keep the optical elements 31 to 33 in a certain position relative to each other and at a defined distance from the surface of the beam-guiding elements or μLEDs 20.

In the present embodiment example, each optical element 31 to 33 covers a total of 4 electronic assemblies including their beam guiding elements. In other words, the optical assembly 30 is thus used by a total of 4 optoelectronic devices with their respective associated beam-guiding elements. This is possible, but not mandatory as shown below. Rather, different optical components can be combined in this way and adapted to the radiation characteristics of the beam-carrying elements. Furthermore, it is possible to manufacture the optical assembly separately from the other elements and to position it accordingly in a separate step.

FIG. 3 shows an embodiment of an optoelectronic assembly according to the proposed principle, in which a plurality of μLEDs are arranged on a carrier 10 and provided with beam-guiding elements. For simplicity, various possible beam-guiding elements are shown here. However, it is immediately apparent that, depending on the application, only individual or certain combinations of these beam-guiding elements are used. This embodiment is therefore to be understood as exemplary and not as a directly implemented optoelectronic assembly.

FIG. 3 shows an optoelectronic assembly 1a with three μLEDs 20r, 20g and 20b combined into groups. The respective μLEDs generate light of different colors (red, green and blue) in one operation and thus each represent a subpixel of a single pixel. By grouping them into groups of three, the structure of a pixel consisting of three differently colored sub-pixels becomes clear. Each μLED 20r, 20g and 20b is placed on a corresponding contact area 11 for this purpose, with this contact area leading to two contact terminals 12 and 13, respectively. The contact terminals 12 and 13 are designed here as planar elements so that they can be electrically contacted with bonding wires or other measures. Depending on the embodiment, the contact terminals 12 and 13 can also lead to feed lines within the substrate carrier 10, so that an electrical connection of the light emitting diodes 20r, 20g and 20b, which are formed as horizontal elements, is made through the substrate carrier 10.

A beam guiding element is formed on and above each μLED, three of which are shown here in their exemplary form. It is understood that, depending on the desired application, only one of these three illustrated beam-guiding elements may be formed in order to obtain the desired radiation pattern. In special applications, it may be intended to combine the beam-guiding elements shown here to compensate for additional negative effects or to realize advantages.

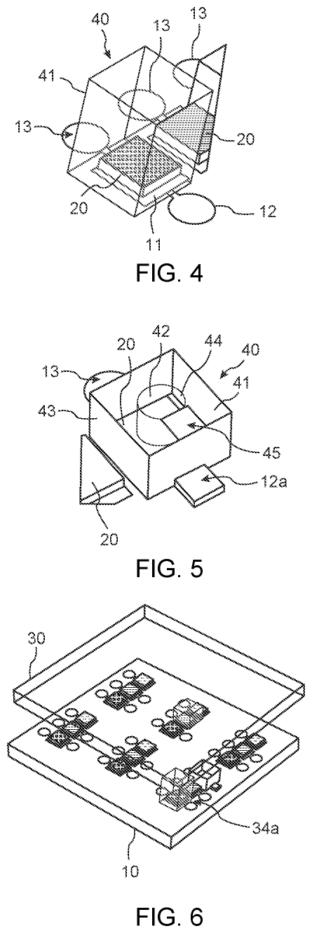

The first beam-guiding element 40 is made with a transparent material 41 and comprises a cuboidal structure that completely surrounds and covers the optoelectronic device 20b. A second beam-guiding element 40c is implemented in a similar manner, but additionally has a reflective layer on the side surfaces of the surface of the transparent material. Both embodiments are further detailed in FIG. 4 and FIG. 5, respectively.

Another beam guiding element 40 is arranged above a μLED tog and is similar in shape to the first beam guiding element. However, it is rather cube-shaped, i.e. its height is smaller than that of the first beam-guiding element, which is arranged above the optoelectronic device 20b.

FIG. 4 shows a design of the first optoelectronic assembly with a μLED 20 and a beam-guiding element 40 arranged above it. The μLED 20 is designed as a flip chip and arranged with its two contacts (not shown here) on the underside on a contact area 11 with two contact areas. The contact area, respectively one contact area each (also not shown) is electrically led out at 2 connections 12 and 13, so that in one operation an operating voltage can be applied to the μLED 20. The μLED 20 comprises an edge length of a few micrometers, for example in the range of 5 μm to 20 μm. Its height is also in the range of a few micrometers, for example between 2 μm and 10 μm.

Due to its small dimensions, the μLED 20 essentially acts as a volume emitter, i.e. in one operation, light is emitted not only along the top surface but also along the side surfaces. On the one hand, this not only reduces the overall light output, but can also lead to undesirable optical crosstalk and a reduction in contrast. According to the proposed principle, a beam guiding element 40 is now provided which completely surrounds the μLED 20. In the embodiment shown, the beam-guiding element is designed as a cuboid, thus has the same basic shape as the μLED 20 and completely surrounds it. In other words, the base area of the beam-guiding element 40 is selected such that it projects beyond the base area of the μLED 20 as well as the edges of the contact area 11. The footprint is thus larger, although the ratio between the footprint of the μLED and the footprint of the beam-guiding element may vary depending on the application.

The beam guiding element 40 is formed with a transparent material 41, and further comprises beam guiding features that substantially deflect and couple light to and from the top surface of the beam guiding element 40. Such beam guiding can be achieved, by way of example, by a refractive index jump between the transparent material 41 and the surrounding medium.

Similarly, it is possible to vary the shape of the transparent material to provide appropriate beam guidance. Photolithographic techniques can thus be used to structure a beam-guiding element made of a radiation-stable plastic. This plastic forms the first imaging optic of an entire optical system of the optoelectronic assembly. A further optical assembly can be arranged downstream of the radiation direction of the beam-guiding element. In addition, the structured beam-guiding element 40 shown here allows a defined placement of an optical assembly and thus a defined distance from the surface of the μLED 20.

In some aspects, further measures may also be provided to improve the reflective properties of the beam guiding element or to ensure electrical contacting to the μLED. FIG. 5 shows a possible embodiment in this regard. In this case, the optoelectronic device 20 is designed as a vertical μLED. In a vertical μLED, in contrast to a μLED in flip-chip technology, the two connection contacts of the μLED are on opposite main sides. In the present case, this would be the bottom side of the μLED 20, which is not visible here, and the top side, which is also the main emission side, although the μLED also emits light via the side surfaces during operation. In order to thus ensure electrical contacting, in this embodiment example the transparent material 41 of the beam guiding element 40c is provided with an additional reflective and electrically conductive layer 43. This completely surrounds the side surfaces of the beam guiding element 40c, but leaves the top surface of the beam guiding element substantially exposed.

The electrically conductive layer 43 is also electrically connected to the contact terminal 12a. A small contact tongue 45, which in the present embodiment is formed of a transparent conductive material, is now provided on the upper surface of the beam guiding element 40c. The contact tongue 45 leads to a recess 44, which is designed as an opening through the beam-carrying element 40c and extends to the contact on the surface of the μLED 20. The inside of the recess or breakthrough 42 is lined with a transparent conductive layer 44 and contacts, on the one hand, the contact tongue 45 and, on the other hand, the contact on the surface of the μLED 20.

Contact tongue 45 and layer 44 may be formed of ITO or a transparent conductive oxide, for example. In this way, the second contact on the top surface of the μLED 20 is electrically conductively connected to the contact terminal 12a. At the same time, during operation of the device, the reflective layer 43 on the side walls of the beam guiding element 40c causes light to be reflected and emitted towards the side. This light is reflected and decoupled upwardly from the beam guiding element.

FIG. 6 shows a perspective view of the basic structure of an optoelectronic assembly together with an optical assembly 30 to form an overall optical system. Here, the optical system 30 is spaced from the surface of the individual μLEDs by means of the beam guiding elements, which thus form spacers 34a. With a common height of all beam guiding elements, the optical assembly can be placed directly without leaving a cavity or an additional refractive index jump between the beam guiding elements and the optical assembly. The use of the beam guiding element as a spacer 34a is thus advantageous, since the design of the beam guiding element simultaneously defines a distance between the optical assembly 30 and the carrier 10 as well as the μLEDs located thereon.

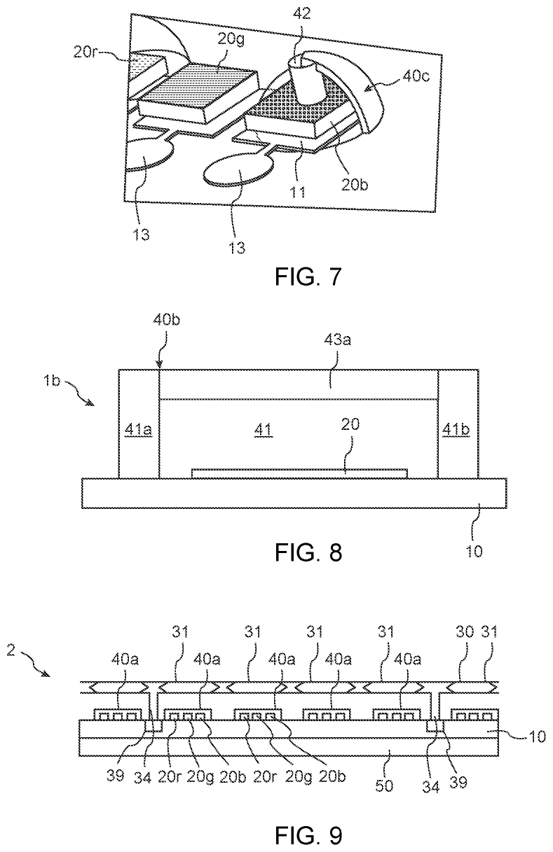

FIG. 7 shows a perspective cross-sectional view of a further embodiment of an electronic assembly according to the proposed principle. Similar to the previous embodiments, a carrier 10 is provided on whose contact regions 11 a plurality of μLEDs 20b, 20g, 20r are arranged. The μLEDs are configured as vertical μLEDs. The beam guiding element 40c is designed as a semicircular element with an additional reflection layer and a central breakthrough 42. The shape of the beam guiding element 40c allows a different optical beam guiding, which can also be different from adjacent μLEDs as shown in FIG. 7. In this way, different beam guiding elements can be provided for optoelectronic devices, so that the beam guiding can be adapted to the respective optoelectronic devices as well as the desired application. In addition, the μLEDs can also be surrounded by differently shaped beam guiding elements. For example, a μLED that produces a blue light during operation may be encased in a beam-guiding element that is different from a beam-guiding element for a red μLED. Possibly, in some embodiments, the beam-guiding elements may be omitted altogether so that light shaping occurs only via the optical assembly downstream in the beam path.

In the embodiment example, the breakthrough 42 is created by drilling, laser melting, or etching the applied beam guiding element. In the embodiment example, the breakthrough 42 is centrally located. However, in some embodiments, it may be convenient to provide the contact terminal of the μLED not centrally, but offset at an edge of the μLED or electronic component. In this case, the beam guiding element together with the breakthrough or recess can possibly be designed differently, for example with an indentation or notch. This also exposes the contact connection on the surface of the optoelectronic device. By means of an additional electrically conductive layer on the surface of the beam-guiding element, this area can be electrically contacted.

FIG. 8 shows a possible modification in which the light is not emitted upwards but to the side. This form is useful for special applications where illuminants serve as background lighting and are not intended to produce direct light (i.e. light that is emitted directly forwards or upwards). In the embodiment of FIG. 8, the optoelectronic device 20 is arranged on the substrate carrier 10, where it is electrically contacted. Surrounding the optoelectronic device 20 both from its side and from its surface is a transparent material 41. A reflective layer 43a is applied to the upper surface of the transparent material 41. On the other hand, the side surfaces are further lined with a transparent material 41a.

Converter particles for light conversion are filled in this transparent material 41a to convert the light emitted from the optoelectronic device 20 into light of a second wavelength, thereby achieving light mixing. The amount of converter material within the regions 41a depends on the dimension of these regions, as well as the conversion efficiency of the converter material used. Due to the small dimensions in the range of a few micrometers, quantum dot converters, which are characterized by a high efficiency in light conversion, are particularly suitable for light conversion. Due to the reflective layer 43a, light that is emitted upwards is redirected into the layer 41. In addition, for further enhancement, the material 41 may include reflective particles that scatter light and thus emit light primarily toward the side regions 41a.

In the embodiment, the device 20 is designed as a flip chip, i.e., it is contacted from the substrate side. This simplifies the formation of the reflective layer 43a. However, it may also be provided to electrically contact this layer 43a, and in turn electrically connect this layer 43a to a contact on the surface of the device 20, if this is designed as a vertical μLED.

In the previous embodiment examples, the beam-carrying element is arranged over exactly one electronic component in each case. Thereby, the beam guiding element may have different shapes or materials depending on the desired beam guidance. In another embodiment, however, beam-guiding elements can also be provided which are arranged over several optoelectronic devices and thus perform common beam shaping for several μLEDs.

FIG. 9 shows a corresponding embodiment, here in the form of a display 2, in which individual optoelectronic devices 20r, 20g and 20b are combined as subpixels to form a pixel and are enclosed by a beam-guiding element 40a. The display 2 includes drive electronics 50 implemented in a dedicated substrate and in electrical communication with a carrier substrate 10. The carrier substrate houses control lines that lead to the individual μLEDs 20r, 20g and 20b so that they can be individually controlled. One μLED 20r, 20g and 20b each form a subpixel of a pixel, so that one μLED each of the corresponding colors red, green and blue are combined to form a pixel. This pixel is in turn spaced from a neighboring pixel.

In order to ensure a color impression that is as uniform as possible, it is now provided that each μLED 20r, 20g and 20b of a pixel is surrounded by a common beam-guiding element 40a. The common beam guiding element 40a thus covers the upper side of each pixel and its side surfaces and thus completely encases the 3 μLEDs. The beam guiding elements 40a are designed in such a way that they radiate the light emitted by the μLEDs upwards and simultaneously provide for color mixing. This results in a uniform color impression for a user, since a spatial resolution of the individual colors is no longer possible due to the beam guiding element 40a.

In addition to the beam-carrying element 40 of each pixel, an optical assembly 30 is provided, exemplarily comprising a plurality of optical collimating elements 31. These are integrated in the optical assembly and are positioned so that they are each located above a beam guiding element 40a of each pixel. The collimating elements 31 together with the beam guiding elements form an optical system for each pixel. At regular intervals, in the illustrated embodiment every 4 pixels, a spacer 34 is provided for the optical assembly 30 to engage with a respective retaining element 39 on the substrate side, thereby positioning the optical elements 31 precisely over the respective beam carrying elements. The interlocking of the spacers 34 and the retaining elements 39 of the substrate 10 provides accurate positioning of the optical assembly over the beam carrying elements.

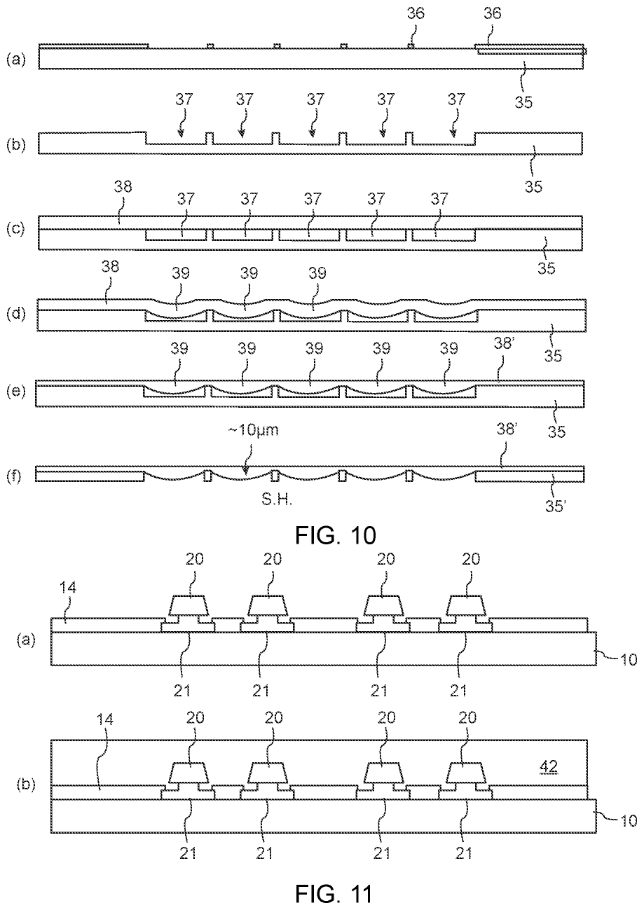

FIG. 10 shows an embodiment of a method for manufacturing an optical assembly that can be used for an optical system according to the proposed principle. In a first step of Figure boa, a support carrier 35 is provided, on the surface of which a patterned photoresist 36 is produced in several steps. For this purpose, the structured photoresist is spun on, then exposed with a mask and the unexposed photoresist material is removed again. The support carrier comprises, by way of example, silicon or other suitable material.

In the step of FIG. 10b, the thus structured support carrier 35 is etched so that a plurality of depressions 37 are formed. The length and size of the recess 37 is selected so that the desired lens shape can be produced in the later steps. Subsequently, in a next step shown in Figure boa, a glass layer is arranged over the support carriers and this is subjected to a thermal process in the step shown in FIG. 10d. Instead of a glass layer by means of spin-on glass, a plastic, a silicone or silicone-containing material, special glasses with low melting point or other suitable materials can be used. In principle, the same materials can be used as for the beam guiding elements and additionally other materials especially suited for optical beam shaping. When using the same material as in the beam guiding element, a refractive index jump at the transition is reduced. On the other hand, such a jump can also be deliberately created by using different materials for the optical element and the beam guiding element.

This changes the viscosity of the glass layer 38 so that lenticular structures 39 are formed in the etched depressions. In this process, the shape of the lens-shaped structures 39 can be adjusted by the temperature, time duration, height and width of the indentation. After a subsequent cooling step, the glass layer 38 is ground back, or more generally ablated, until a planar surface with the desired dimension for the individual lenticular structures 39 is obtained.

In a further step, the support carrier 35 can also be ground back until the individual lens structures 39 are exposed, resulting in the optical assembly shown in FIG. 10F. The columns left between the individual recesses 37 can now be used as support structures for the optical assembly.

FIGS. 11a and 11b show two process steps for producing an electronic assembly according to the proposed principle. In FIG. 11a, a substrate carrier 10 is provided on which a dielectric layer 14 is deposited. The substrate carrier can also be formed with various conductive structures not shown here in order to drive the μLEDs that are applied later. Recesses are made in the dielectric layer 14 on the surface of the substrate 10 to receive a plurality of μLEDs 20 in a subsequent transfer process. In this process, the μLEDs are arranged on pillar-forming structures 21.

The structures 21 and the μLEDs 20 can be manufactured in different ways. In one embodiment, they are fabricated directly on the carrier substrate 10 via several photolithographic steps and further measures, with the material in the spaces between the individual μLEDs 20 the support and holding structures 21 being removed again by subsequent etching processes. This creates an integrated unit between the carrier 10 and the devices 20. The structures 21 can also be omitted in manufacturing, so that the μLEDs 20 are created directly on the carrier using photolithographic processes.

Alternatively, transfer processes can be used in which, as shown in this embodiment, μLEDs are transferred from an auxiliary carrier, which is not shown, to the carrier substrate 10 and then electrically conductively connected to it.

In a subsequent step shown in IG. 11b, a flat layer of transparent plastic 42 is applied so that it completely surrounds the individual μLEDs 20. In addition, the material of the plastic also enters the spaces between the retaining structures and the μLED 20. Suitable materials for the transparent plastic include glass, silicone or silicone-containing materials, acrylic or acrylic-containing materials, and organic-inorganic hybrid materials. These are sputtered on, spun on or otherwise applied and cured so that a planar surface results.

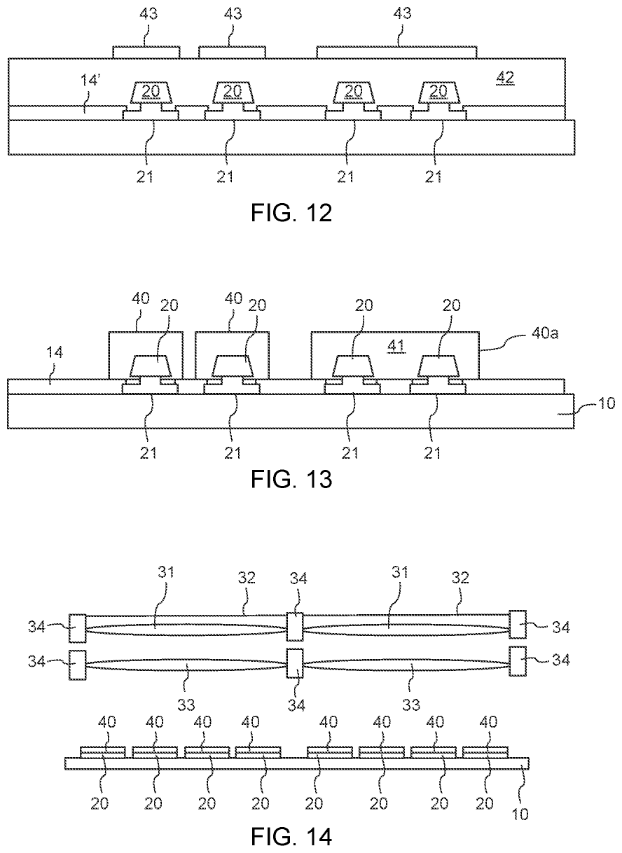

In a subsequent process step, shown in FIG. 12, a photoresist layer is applied to the transparent material 42 and structured by means of a mask. In the embodiment shown in FIG. 12, photoresist elements are shown, each of which is located over a single μLED 20 or a pair of two μLEDs 20. In a subsequent step, an etching process is now performed by removing the pails of the transparent plastic 42 that are not covered by photoresist. The etching process is performed in such a way that the material is removed down to the dielectric layer 14. However, cuboidal or other shaped structures remain around the components 20, which now form part of the beam guiding elements 40.

In particular, the application and structuring of the photoresist 43 is carried out in such a way that, after an etching process, transparent plastic material remains not only on the upper side of the respective μLED, but also on the side surfaces of the μLEDs. The transparent plastic material thus completely surrounds each optoelectronic device, whereby a distance between the component and the transparent material is set by the structure and etching process.

FIG. 13 now shows 2 different beam guiding elements 40 and 40a. The beam guiding elements 40 each encase a single μLED 20, while the beam guiding element 40a encases two adjacent μLEDs 20.

In an alternative embodiment, the material 42 may additionally be mixed with converter materials or reflective particles during the manufacturing process. Likewise, further thermal steps may be performed after or even during an etching process, so that the beam guiding elements are once again modified in their shape. In this way, beam shaping of the type desired for the application can be realized.

In a final step shown in FIG. 14, an optoelectronic assembly produced in this way can now be combined with additional optical assemblies. For this purpose, the optical assemblies are positioned, aligned and then fixed on the carrier 10 by means of their spacers, as shown for example in FIG. 10.

By combining different optical assemblies, an application-specific optical system can thus be realized. The optical system is integrated as an optical unit and, in addition to optoelectronic devices, in particular in the form of μLEDs or microsensors, includes beam-guiding elements that suitably deflect radiation emitted to the side in the case of particularly small components. With the aid of the proposed process, various optical structures can be produced as beam-guiding elements on optoelectronic devices and combined with other optics. In this respect, various known technologies for manufacturing optical assemblies can also be combined with the solution according to the invention.

With a suitable choice of transparent material, both the beam-carrying elements themselves and separate spacers can be used as spacers. The beam guiding elements can be produced by lithographic structuring and thermal treatment. Among other things, plasma etching can be used to remove superfluous transparent material. Lenses and other optical elements can be formed via temperature steps. Furthermore, it is also possible to accommodate converter materials, optical waveguides or even photonic structures in both the beam guiding elements and the optical elements. Accordingly, different radiation characteristics are realized in this way depending on the application.

1.-31. (canceled)

32. An optoelectronic assembly comprising:
a carrier having at least one contact region;
at least one optoelectronic device configured to generate electromagnetic radiation, the optoelectronic device arranged on the at least one contact region;
a beam guiding element comprising a transparent material, arranged on the carrier, completely encasing the optoelectronic device and at least partially covering surface areas of the optoelectronic device,
wherein the beam guiding element sheaths at least three optoelectronic devices and covers the surface areas of the optoelectronic devices, and
wherein the optoelectronic devices are configured to generate light of different colors; and
a transparent conductive layer arranged at the beam guiding element at least in some regions on its surface,
wherein the beam guiding element comprises a recess through which the at least one contact region is exposed on a side of the optoelectronic device facing away from the carrier, and
wherein the recess is at least partially filled with a conductive material which is connected to the transparent conductive layer.

33. The optoelectronic assembly according to claim 32, wherein a base shape of the beam guiding element corresponds to a shape of a base of the optoelectronic device, and wherein the optoelectronic device overhangs the beam guiding member in this shape.

34. The optoelectronic assembly according to claim 32, wherein the at least one optoelectronic device is a volume emitter.

35. The optoelectronic assembly according to claim 32, further comprising a reflective layer arranged at to the beam guiding element at least in regions adjacent to the side surfaces of the optoelectronic device.

36. The optoelectronic assembly according to claim 32, wherein the beam guiding element has a reflective layer on a side opposite the carrier, and wherein the reflective layer is at least partially transparent to light at least in regions adjacent to the side surfaces of the optoelectronic device.

37. The optoelectronic assembly according to claim 32, wherein the recess forms a breakthrough.

38. The optoelectronic assembly according to claim 32, wherein the beam guiding element comprises a lens.

39. The optoelectronic assembly according to claim 32, wherein the beam guiding element comprises at least one of the following materials:
SiO₂ or spin-on glasses;
silicone-containing materials;
acrylics or acrylic-containing materials;
low melting glasses based on tellurite glass, bismuth glass, or vanadate glass;
scattering particles based on TiO₂;
a converter material configured to convert light of a first wavelength into light of a second wavelength; or
a quantum dot converter material.

40. The optoelectronic assembly according to claim 32, further comprising an optical assembly disposed over the beam guiding element, the optical assembly optionally comprising a support carrier for supporting one or more optical elements.

41. The optoelectronic assembly of claim 40, wherein the optical assembly comprises:
a lens;
a λ/2 layer or a λ/4 layers;
a converter configured to convert light of a first wavelength into light of a second wavelength; or
photonic structures.

42. The optoelectronic assembly according to claim 40, further comprising at least three spacers arranged on the carrier or on the optical assembly and configured to fix the optical assembly at a defined distance from the carrier.

43. The optoelectronic assembly according to claim 41, wherein the at least three spacers are at least partially formed by beam guiding elements, the beam guiding elements having a planar upper surface.

44. The optoelectronic assembly according to claim 32, wherein the further optical assembly is arranged above at least three beam guiding elements, each surrounding at least one optoelectronic device and configured to generate light of different wavelengths.

45. The optoelectronic assembly according to claim 32, wherein a beam guiding element which completely encases the at least one optoelectronic device is spaced apart from an adjacent beam guiding element which completely encases at least one further optoelectronic device.

46. A display arrangement comprising:
at least one optoelectronic assembly according to claim 32; and
a drive circuit configured to drive the optoelectronic devices of the at least one assembly.

47. A method for manufacturing an optoelectronic assembly, the method comprising:
providing a carrier having at least one contact region;
forming at least one optoelectronic device on the at least one contact region, the optoelectronic device configured to generate electromagnetic radiation;
applying a transparent material to the carrier and to the at least one optoelectronic device so that the latter is completely surrounded by the transparent material;
structuring the transparent material; and
forming a beam guiding element completely surrounding the at least one optoelectronic device and at least partially covering surface areas of the optoelectronic device, wherein forming the beam guiding element comprises:
applying a transparent conductive layer in form of a contact tongue to at least some regions of the beam guiding element;
forming a recess in the beam guiding element such that a contact area is exposed on a side of the optoelectronic device facing away from the carrier; and
at least partially filling the recess with a conductive material bonded to the transparent conductive layer.

48. The method according to claim 47, wherein structuring the transparent material comprises:
applying a photoresist to the transparent material; and
patterning the photoresist such that a shape of the patterned photoresist corresponds to a shape of a base surface of the optoelectronic device.

49. The method according to claim 47, wherein forming the beam guiding element comprises at least partially removing the transparent material between regions of two optoelectronic devices such that the transparent material surrounding the optoelectronic device is spaced apart from a material surrounding an adjacent optoelectronic device.

50. The method according to claim 47, wherein forming the beam guiding element further comprises:
applying a reflective layer at least in regions adjacent to the side surfaces of the optoelectronic device; and
applying the reflective layer on a side of the beam guiding element opposite the carrier, at least at regions adjacent to the side surfaces of the optoelectronic device remaining at least partially transparent to light.

51. The method according to claim 47, wherein the recess forms a cylindrical breakthrough.

52. The method according to claim 47, wherein forming the beam guiding element comprises forming a lens.

53. The method according to claim 47, wherein forming the at least one optoelectronic device comprises:
forming at least two optoelectronic devices; or
forming a plurality of optoelectronic devices, which are combined into groups, each group comprising optoelectronic devices are configured to generate light of different colors.

54. The method according to claim 47, wherein structuring the transparent material and forming the beam guiding element are carried out such that the optoelectronic devices combined into groups are each surrounded by a common beam guiding element.

55. The method of claim 47, further comprising:
providing an optical assembly;
disposing the optical assembly over the beam guiding element; and
fixing the optical assembly to the carrier so that the optical assembly is at a defined distance from the carrier.

56. The method according to claim 55, wherein the optical assembly comprises:
a lens;
a waveguide;
a λ/2 layer or a λ/4 layer;
a converter configured to convert light of a first wavelength to light of a second wavelength; or
a photonic structure.

57. The method according to claim 55, wherein providing the optical assembly comprises forming or providing the optical assembly with at least three spacers configured to fix the optical assembly at a defined distance from the carrier and the beam guiding element.

58. The method according to claim 57, wherein the at least three spacers are at least partially formed by beam guiding elements, the beam guiding elements having a planar upper surface.

59. The method according to claim 57, wherein the optical assembly is arranged above at least three beam guiding elements, each of which surrounds at least one optoelectronic device, and which optionally is configured to generate light of different wavelengths.

60. The method according to claim 47, wherein providing the carrier comprises forming or providing the carrier with at least three spacers configured to fix an optical assembly at a defined distance from the carrier and the beam guiding element.
